(19) United States
(12) Patent Application Publication
(10) Pub. No.: US 2024/0371737 A1
(43) Pub. Date: Nov. 7, 2024

(54) PACKAGE SUBSTRATE HAVING ELECTRONIC COMPONENT MOUNTED IN A CAVITY OF A CORE OF THE PACKAGE SUBSTRATE WITH A RESIN

(71) Applicant: QUALCOMM Incorporated, San Diego, CA (US)

(72) Inventors: Hong Bok WE, San Diego, CA (US); Joan Rey Villarba BUOT, Escondido, CA (US); Michelle Yejin KIM, Carlsbad, CA (US); Kuiwon KANG, San Diego, CA (US)

(21) Appl. No.: 18/310,425

(22) Filed: May 1, 2023

(51) Int. Cl. H01L 23/498; H01L 21/48; H01L 23/00

(52) U.S. Cl. CPC H01L 23/49822; H01L 21/4857; H01L 23/49838; H01L 23/49894; H01L 24/16; H01L 28/40; H01L 2224/16227

(57) ABSTRACT

In an aspect, an electronic device is disclosed that includes a substrate comprising a core having an upper planar surface and a lower planar surface, wherein the core includes a cavity extending through the core; an electronic component at least partially disposed in the cavity, wherein the electronic component has an upper planar surface having one or more electronic component terminals; a first cured resin layer, wherein the upper planar surface of the electronic component is at least partially embedded in the first cured resin layer at least at an upper portion of the cavity; and an upper metallization structure disposed over the upper planar surface of the core, wherein the upper metallization structure is configured to provide one or more conductive paths from the one or more electronic component terminals to one or more upper metal terminals of the upper metallization structure.

### FIELD OF DISCLOSURE

The present disclosure generally relates to a package substrate, and more particularly, to a package substrate having an embedded electronic component mounted in a core of the package substrate.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

In some implementations, embedded passive devices, such as deep trench capacitors, have been incorporated in IC packaging for performance improvement and package size reduction. One factor driving the use of such embedded passive devices is the desire to obtain small form factor products with equivalent or better electrical performance than their larger passive device counterparts. Depending on the size and/or thickness of the package substrate and the size and/or the process node of the IC Chip carried thereon, the process for embedding a passive device in a package substrate in one packaging task may not be suitable for another packaging task.

Accordingly, there is a need for improved methods for embedding an electrical component in a substrate, such as a package substrate, which may be suitable for a broader variety of packaging tasks.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes a substrate comprising a core having an upper planar surface and a lower planar surface, wherein the core includes a cavity extending between the upper planar surface of the core and the lower planar surface of the core; an electronic component at least partially disposed in the cavity, wherein the electronic component has an upper planar surface having one or more electronic component terminals; a first cured resin layer, wherein the upper planar surface of the electronic component is at least partially embedded in the first cured resin layer at least at an upper portion of the cavity; and an upper metallization structure disposed over the upper planar surface of the core, wherein the upper metallization structure is configured to provide one or more conductive paths from the one or more electronic component terminals to one or more upper metal terminals of the upper metallization structure.

In an aspect, a substrate includes a core having an upper planar surface and a lower planar surface, wherein the core includes a cavity extending between the upper planar surface of the core and the lower planar surface of the core; an electronic component at least partially disposed in the cavity, wherein the electronic component has an upper planar surface having one or more electronic component terminals; a first cured resin layer, wherein the upper planar surface of the electronic component is at least partially embedded in the first cured resin layer at least at an upper portion of the cavity; and an upper metallization structure disposed over the upper planar surface of the core, wherein the upper metallization structure is configured to provide one or more conductive paths from the one or more electronic component terminals to one or more upper metal terminals of the upper metallization structure.

In an aspect, a method for making a substrate includes forming a cavity in a core, wherein the cavity extends between a first planar surface of the core and a second planar surface of the core; mounting an electronic component at least partially in the cavity, wherein the electronic component includes a first planar surface having one or more electronic component terminals, and wherein the first planar surface of the electronic component is at least partially embedded in a first cured resin layer at a first end of the cavity; and forming a first metallization structure over the first planar surface of the core, wherein the first metallization structure is configured to provide one or more conductive paths from the one or more electronic component terminals to one or more metal terminals of the first metallization structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of an example substrate with an embedded electronic component, according to aspects of the disclosure.

FIG. 2 is a cross-sectional view of the example substrate showing the propagation of the voids in the dielectric material and the resulting defects, according to aspects of the disclosure.

FIG. 3 is a cross-sectional view of an example trench capacitors (DTC), according to aspects of the disclosure.

FIGS. 4A and 4B are cross-sectional views of an example substrate, according to aspects of the disclosure.

FIGS. 5A through 5D illustrate example operations that may be performed during the fabrication of an example substrate, according to aspects of the disclosure.

FIGS. 6A and 6B are cross-sectional views of an example substrate, according to aspects of the disclosure.

FIGS. 7A through 7E illustrate example operations that may be performed during the fabrication of an example substrate, according to aspects of the disclosure.

FIG. 8 is a flowchart showing an example method of fabricating a substrate, according to aspects of the disclosure.

FIG. 9 illustrates a profile view of a package that includes a surface mount substrate, an integrated device, and an integrated passive device, according to aspects of the disclosure.

FIG. 10 illustrates an example method for providing or fabricating a package that includes an integrated device comprising package substrate, according to aspects of the disclosure.

FIG. 11 illustrates various electronic devices that may be integrated with any of the disclosed package substrates, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments.

In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

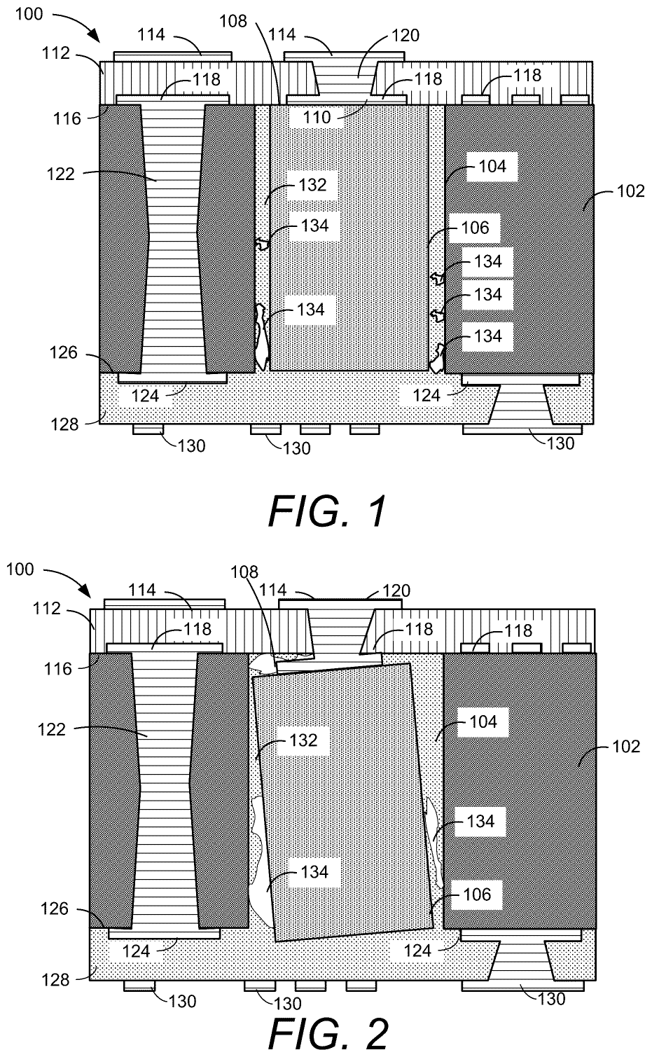

FIG. 1 is a cross-sectional view of an example substrate 100 with an embedded electronic component, according to aspects of the disclosure. In this example, the substrate 100 includes a core 102 having a cavity 104 that extends entirely through the core 102. An electronic component 106 is disposed within the cavity 104. The electronic component 106 has an upper planar surface 108 with one or more electronic component terminals 110. In accordance with various aspects of the disclosure, the electronic component 106 may be one or more of an active electronic component, a passive electronic component (e.g., a deep trench capacitor (DTC)), a die, etc.

In accordance with various aspects of the disclosure, the substrates described herein (e.g., substrate 100) that include a core and an embedded electronic component are directed to package substrates. A package substrate is the part of an integrated circuit package that gives the board its mechanical strength and allows it to connect with external devices. Such package substrates are to be distinguished from other substrates, such as the substrates that may be included in the embedded electronic component itself, dies including substrates (e.g., silicon substrates or other similar electronic devices).

The substrate 100 further includes a plurality of dielectric layers 112 and patterned metallization layers 114 overlying an upper planar surface 116 of the core 102 (only one such dielectric layer and corresponding patterned metal layer overlying the upper planar surface 116 are shown in FIG. 1). A patterned metallization layer 118 including a via structure 120 is disposed at the upper planar surface 116 of the core 102 to provide an electrical connection between the one or more electronic component terminals 110 and the patterned metallization layers 114.

In this example, one or more vias 122 extend through the core 102 and connect the patterned metallization layer 118 at the upper planar surface 116 of the core 102 with a further patterned metallization layer 124 at a lower surface 126 of the core 102. A further plurality of dielectric layers 128 and patterned metallization layers 130 are formed over the lower surface 126 of the core 102 (only one such dielectric layer and corresponding patterned metal layer formed over the lower surface 126 are shown in FIG. 1).

In an aspect, the same dielectric material as used in forming the dielectric layers 128 may be used to fill the cavity 104. Commonly used dielectric materials include Ajinomoto Build-Up Film® (ABF), PPG® liquid resins, and the like. During the manufacture of the substrate 100, the electronic component 106 is inserted in the cavity 104 before the dielectric resin is injected to fill the regions 132 between the cavity 104 and the electronic component 106. During insertion, the electronic component 106 is carefully aligned within the cavity 104 to ensure that the one or more electronic component terminals 110 properly contact and electrically bond with the corresponding portions of the patterned metallization layer 118. Additionally, the injection of the dielectric resin in the regions 132 should be undertaken with care so as not to disturb the initial alignment of the electronic component 106 within the cavity 104. In an aspect, the dielectric resin, once cured, secures the electronic component 106 at its proper location within the cavity 104.

Current trends in package substrate design are directed to applications that present unique design and manufacturing issues (e.g., need for reduced substrate warpage, a need for cavities that accommodate large electronic components, a need for larger keep-out zones, etc.). These issues may be addressed, at least in part, by employing thick cores in the design and manufacture of such substrates. For example, warpage control is more easily achieved with thick cores than with thin cores. Additionally, the need for larger cavity sizes and keep-out zones can be met by employing such thick cores. In certain scenarios, cores (e.g., both thick and thin cores) may be required to accept large, embedded electronic components in which the electronic component occupies a substantial volume of the cavity in which the electronic component is embedded.

However, substrates employing thick cores or requiring large, embedded electronic components may be difficult to manufacture using the same packaging technologies that are used in manufacturing substrates having thin cores and/or smaller embedded electronic components. With thick cores, there is a significant gap between the electronic component and the cavity resulting from the increased depth of the cavity compared to the height of the electronic component (e.g., the thick core has a thickness that is greater than the height of the die). In such thick core scenarios, it may be difficult or impossible to fill the cavity (e.g., particularly the regions between the exterior of the electronic component and the interior walls of the cavity) with the commonly used dielectric resins (e.g., Ajinomoto Build-Up Film® (ABF), PPG® liquid resins, etc.) without voids in the resulting dielectric material in which the electronic component is ultimately embedded. Similarly, when the electronic component takes up a substantial volume of the cavity, it may be difficult to adequately fill the small regions between the electronic component and the cavity with the commonly used dielectric resins without voids in the resulting dielectric material in which the electronic component is ultimately embedded.

FIG. 1 shows voids 134 in the dielectric material filling the cavity 104 that occur when the regions between the interior surfaces of the cavity 104 and the exterior surfaces of the electronic component 106 are not adequately filled with the dielectric material. In FIG. 1, the voids 134 in the dielectric material have not presented an immediate problem with the connection between the one or more electronic component terminals 110 and the patterned metallization layer 118. However, the voids 134 may propagate through the dielectric material as a result of the thermal and/or mechanical stresses that occur during the use of the substrate for its intended purpose.

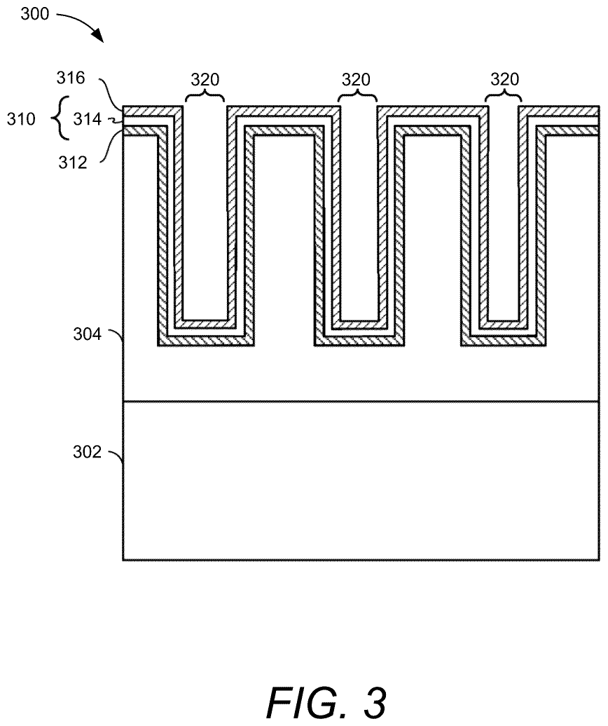

FIG. 2 is a cross-sectional view of the example substrate 100 showing the propagation of the voids 134 in the dielectric material and the resulting defects, according to aspects of the disclosure. For purposes of simplicity, reference numbers used in FIG. 1 have also been used to designate similar elements in FIG. 2.

In FIG. 2, the propagation of the voids 134 has allowed the electronic component 106 to shift its position within the cavity 104, resulting in a delamination of the electronic component 106 from the core 102. Such delamination may result in reduced performance and/or a complete failure of the electronic device in which the substrate 100 is incorporated.

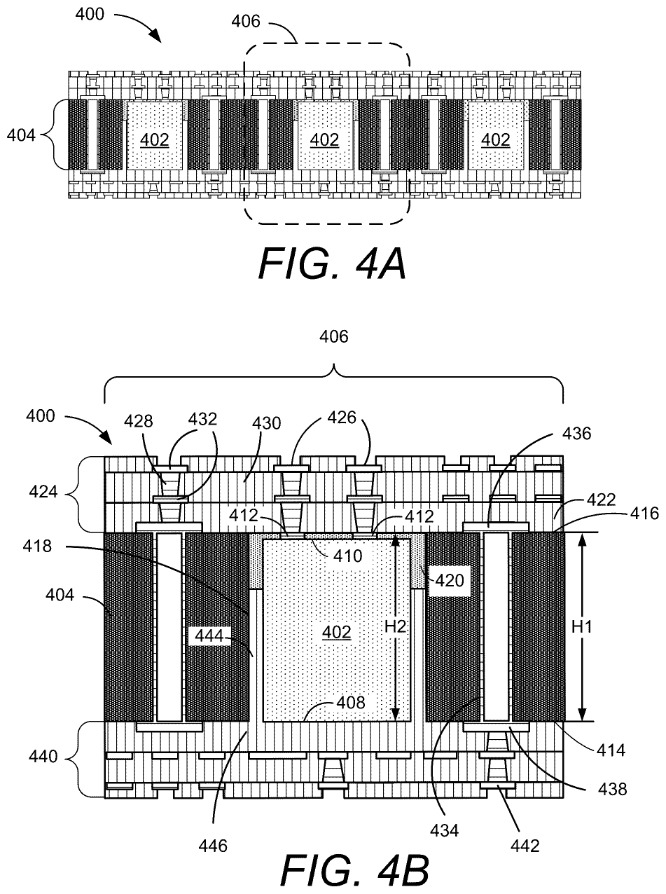

According to certain aspects of the disclosure, the electronic component may be a DTC. FIG. 3 is a cross-sectional view of an example DTC 300, according to aspects of the disclosure. In FIG. 3, a capacitor 310 is deposited in trenches 320 of an insulator 304 on a substrate 302. The capacitor 310 may include a metal layer 312, a dielectric layer 314, and a metal layer 316. The dielectric layer 314 separates the metal layer 312 from the metal layer 316. The metal layers 312, 316 form electrodes of the capacitor 310 and may be connected to terminals at, for example, a surface (see, e.g., the upper planar surface 108 with the electronic component terminals 110 of the electronic component 106 shown in FIG. 1). In some scenarios, the capacitors are formed from an array of deep trenches in a substrate and filled with an electrical insulator (e.g., a dielectric) between layers of electrodes. In some scenarios, the capacitors are attached on the land side under an integrated circuit die shadow (land-side capacitor: LSC) or adjacent to the die on the die side (die-side capacitor: DSC).

Certain aspects of the disclosure are implemented with a recognition of the problems associated with using existing processing technologies and materials to manufacture substrates having thick cores and/or cavities that accommodate large, embedded electronic components. In accordance with certain aspects of the disclosure, the electronic component may be embedded in the cavity using a liquid resin that is dispensed within the cavity and subsequently cured to secure the electronic component within the cavity. Certain aspects of the disclosure are implemented with a recognition that such liquid resins have fluid and other material characteristics (e.g., low viscosity which is helpful with large cavity fills) that allow the liquid resins to substantially fill the regions between the interior surfaces of the cavity and the exterior surfaces of the electronic component without voids thereby providing a more robust embedding of the electronic component within the core of the substrate. From a process perspective, liquid resin fills may be preferable over dielectric layer lamination fills for large cavities since dielectric layer lamination fills may require high pressure and temperature conditions that can lead to shift of the electronic component in the cavity. In accordance with certain aspects of the disclosure, the liquid resin dispensed into the cavity during fabrication of the substrate can be at least partially cured once the electronic component is embedded in the liquid resin, thereby retaining the electronic component in place while the remaining portions of the cavity are filled a filling material (e.g., a dielectric material, a further amount of resin material, etc.). In accordance with certain aspects of the disclosure, and without limitation, liquid resins such as the THP-100DX1 series liquid resin available from Taiyo America, Inc., and the PHP900 series liquid resin available from San-Ei Kagaku Co., Ltd. are suitable for securing the electronic component within the cavity.

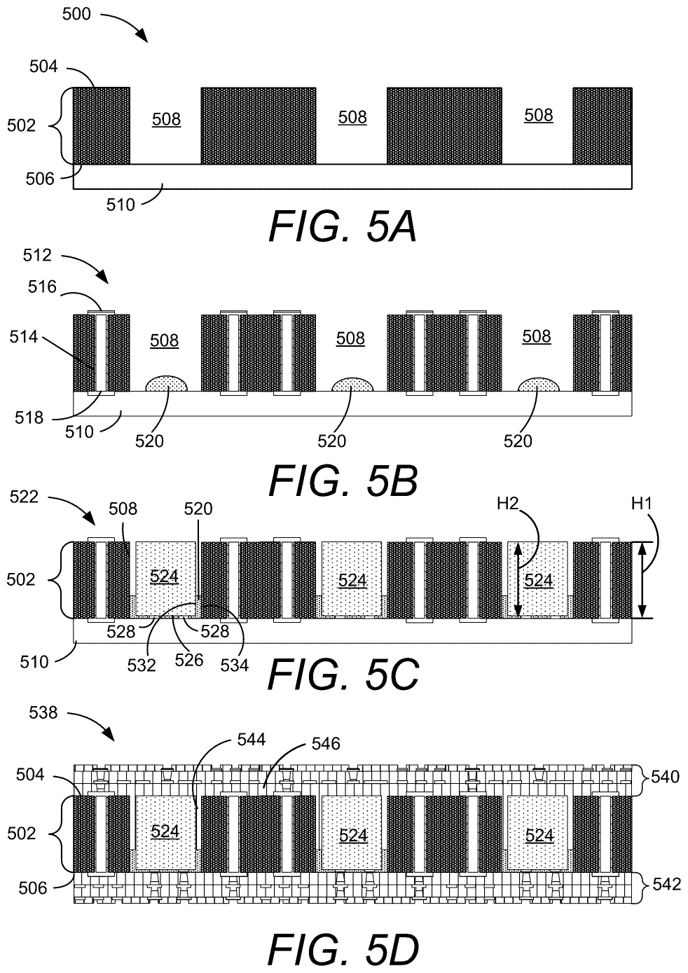

FIGS. 4A and 4B are cross-sectional views of an example substrate 400, according to aspects of the disclosure. As shown in FIG. 4A, the substrate 400 includes an array of electronic components 402 embedded in a core 404. FIG. 4B is an exploded view of region 406 of the substrate 400 shown in FIG. 4A.

As shown in FIG. 4B, the substrate 400 includes an electronic component 402 having a lower planar surface 408 and an upper planar surface 410. The lower planar surface nor 410 of the electronic component 402 includes one or more electronic component terminals 412 providing an electrical connection with the electronic component 402.

The core 404 includes a lower planar surface 414 and an upper planar surface 416. A cavity 418 extends through the core 404 between the upper planar surface 416 and lower planar surface 414. In this example, the thickness H1 of the core 404 is substantially the same dimension as the height H2 of the electronic component 402. In accordance with various aspects of the disclosure, the core 404 may be a thin core having a thickness H1 that is less than or equal to 760 micrometers (μm). Alternatively, the core may be a thick core having a thickness H1 that is greater than 760 μm (e.g., equal to or greater than 820 μm, equal to or greater than 1240 μm, etc.).

In accordance with various aspects of the disclosure, the electronic component 402 is mounted at an upper portion of the cavity 418 in a cured resin layer 420. In the example shown in FIG. 4B, the cured resin layer 420 fills the regions of the cavity 418 between the upper planar surface 410 of the electronic component 402 and a lowermost dielectric layer 422 of an upper metallization structure 424 disposed over the upper planar surface 416 of the core 404. In an aspect, the cured resin layer 420 also at least partially fills the regions of the cavity 418 between the interior sidewalls of the core 404 and the exterior sidewalls of the electronic component 402.

In the example shown in FIG. 4B, the upper metallization structure 424 is configured to provide one or more conductive paths between the one or more electronic component terminals 412 and one or more upper metal terminals 426 of the upper metallization structure 424. The conductive paths are provided by vias (e.g., via 428) extending between one or more dielectric layers (e.g., dielectric layer 430) that connect one or more patterned metal layers (e.g., patterned metal layers 432). In an aspect, the upper metal terminals 426 may be configured for connection with a surface-mounted electronic package (not shown in FIG. 4B). Additionally, or in the alternative, the upper metal terminals 426 may be configured for connecting the substrate 400 with other electronic components (e.g., active components, passive components, integrated circuits, etc.).

Core vias (e.g., via 434) connect one or more of the patterned metal layers (e.g., patterned metal layer 436) of the upper metallization structure 424 with one or more patterned layers (e.g., patterned metal layer 438) of a lower metallization structure 440 to electrically connect the upper metallization structure 424 with the lower metallization structure 440. The lower metallization structure 440 provides one or more conductive paths between the patterned metal layer 438 and one or more terminals 442 of the lower metallization structure 440. The metal terminals 442 may be configured for connecting the substrate 400 with other electronic components (e.g., active components, passive components, integrated circuits, etc.), including surface-mounted electronic packages (not shown in FIG. 4B).

The cured resin layer 420 keeps the electronic component 402 fixed in the cavity 418 and provides a substantially void-free solid material (e.g., having no voids, or having fewer voids and/or voids of smaller dimensions than the voids typically found in conventional dielectric fills used to embed electronic components under similar geometric filling constraints) thereby providing a robust mounting of the electronic component 402 in the cavity 418. As such, the electronic component 402 is secured within the cavity 418 in a manner that limits the chances that the electronic component 402 will delaminate from the core 404.

In an aspect, the cured resin layer 420 may be initially deposited as a liquid resin in the cavity 418. The electronic component 402 may be at least partially embedded in the liquid resin before the liquid resin is cured to form the cured resin layer 420. In this manner, the electronic component 402 may be held in position in the cavity 418 as the remaining portions of the cavity 418 that are not initially filled with the resin are filled with a filling material 444. In the example shown in FIG. 4B, the filling material 444 is a dielectric material. In an aspect, the dielectric material used as the filling material 444 may be the same dielectric material used to form one or more of the dielectric layers (e.g., dielectric layer 446) of the lower metallization structure 440.

Although the dielectric layers of the upper metallization structure 424 are shown in FIG. 4B as separate layers, it will be understood that multiple dielectric layers may be fused during the manufacturing process so as to appear and function as a single dielectric structure. Further, it will be understood that different layers of the dielectric layers of the upper metallization structure 424 may be formed from different dielectric materials during the manufacturing process. In an aspect, different dielectric materials for the different dielectric layers may be used when one or more of the dielectric layers are to have a different dielectric constant than another of the dielectric layers.

Similarly, the dielectric layers of the lower metallization structure 440 are shown in FIG. 4B as separate layers. However, it will be understood that multiple dielectric layers may be fused during the manufacturing process so as to appear and function as a single dielectric structure. Further, it will be understood that different layers of the dielectric layers of the upper metallization structure 424 may be formed from different dielectric materials during the manufacturing process. In an aspect, different dielectric materials for the different dielectric layers may be used when one or more of the dielectric layers are to have a different dielectric constant than another of the dielectric layers.

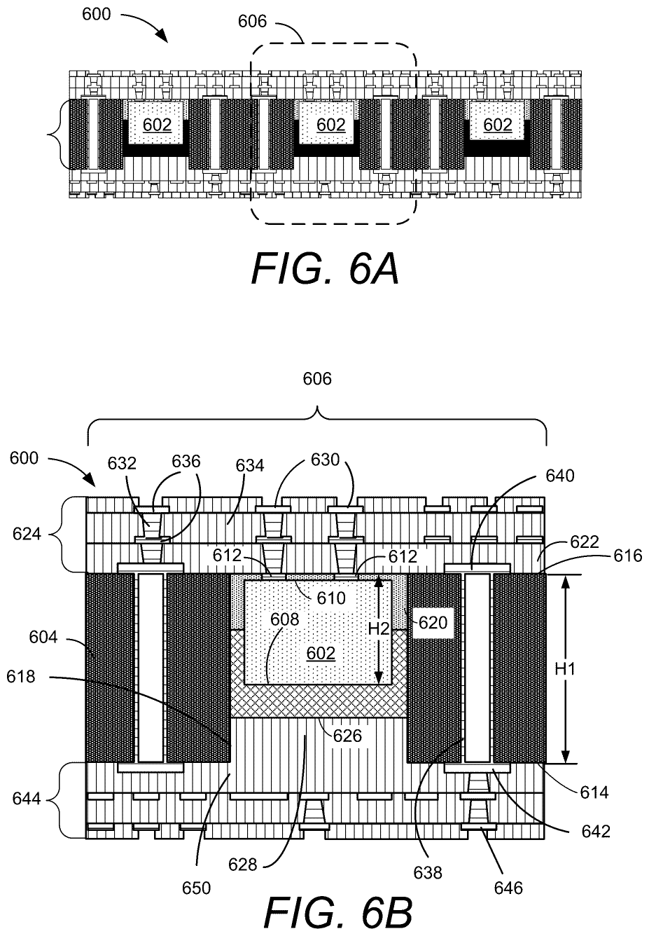

FIGS. 5A through 5D illustrate example operations that may be performed during the fabrication of an example substrate, according to aspects of the disclosure. FIG. 5A shows a first intermediate state 500 of the substrate during the example fabrication process, according to aspects of the disclosure. In this example, the first intermediate state 500 of the substrate includes a core 502 with a first planar surface 504 and a second planar surface 506. In an aspect, the core 502 is subject to a drilling operation to form the cavities 508 that extend between the first planar surface 504 and the second planar surface 506 of the core 502. A layer of a polyimide (PI) tape 510 is secured on the second planar surface 506 of the core 502 over the openings of the cavities 508.

FIG. 5B shows a second intermediate state 512 of the substrate during the example fabrication process, according to aspects of the disclosure. In this example, via holes have been drilled through the core 502. The via holes have been subject to metallization and tenting operations to form core vias (e.g., core via 514). Here, the core vias (e.g., core via 514) connect patterned metallization layers (e.g., patterned metallization layers 516, 518) at the first planar surface 504 and the second planar surface 506 of the core 502. An amount of a liquid resin 520 is placed on a planar surface of the PI tape 510 at a central location within each cavity 508.

FIG. 5C shows a third intermediate state 522 of the substrate during the example fabrication process, according to aspects of the disclosure. Here, an electronic component 524 is inserted in each cavity 508. In this example, each electronic component 524 has a height H2 that is the same dimension as the thickness H1 of the core H1. In accordance with various aspects of the disclosure, the electronic components 524 may be one or more of an active electronic component, a passive electronic component (e.g., a deep trench capacitor (DTC)), a die, etc.

As shown, each electronic component 524 is inserted into the cavity 508 so that a planar surface 526 of the electronic component 524 and its corresponding electronic component terminals 528 are at least partially embedded in the liquid resin 520 of the cavity 508. In this example, the electronic component 524 displaces the liquid resin 520 so that the liquid resin 520 fills the region between the PI tape 510 and the planar surface 526 of the electronic component 524. Additionally, depending on the amount of liquid resin 520 dispensed in the cavity 508, the electronic component 524 may displace the liquid resin 520 to an extent that the liquid resin 520 fills the portions of the sidewalls of the cavity 508 adjacent the electronic component 524 (e.g., fills the regions between the outer exterior sidewalls 532 of the electronic component 524 and the inner sidewalls 534 of the cavity 508). Once each electronic component 524 is positioned within its respective cavity 508, the liquid resin 520 is cured (e.g., thermally cured on a hotplate). The liquid resin 520 now forms a cured resin layer (still identified using reference number 520) in each cavity 508, which retains the electronic component 524 in place during subsequent substrate fabrication operations (e.g., filling of the portions of the cavity 508 that are not yet filled with the cured resin layer 520).

FIG. 5D shows the formation of a completed substrate 538, according to aspects of the disclosure. Here, the layer of PI tape 510 is removed. A first metallization structure 540 is formed over the first planar surface 504 of the core 502 and a second metallization structure 542 is formed over the second planar surface 506 of the core 502. In this example, the portions of the cavity 508 that are not filled with the cured resin layer 520 have been filled with a dielectric material 544. In an aspect, the dielectric material 544 may be the same dielectric material used to form one or more of the dielectric layers (e.g., dielectric layer 546) of the first metallization structure 540.

In accordance with certain aspects of the disclosure, the formation of the metallization layers 540 and 542 may include an initial dielectric lamination operation over each of the planar surfaces 504, 506 of the core 502. The initial dielectric lamination operation may be followed by one or more layer build-up operations. In an aspect, each layer build-up operation may be conducted using a semi-additive process (SAP). In accordance with such SAPs, each dielectric layer is deposited and then laser drilled to form via holes, which are subject to an electroless plating process to deposit metal on the walls of the via holes. If the via structure remains hollow after the electroless plating process, it may be filled with a plugging ink. During the build-up operation, a patterned metallization layer may be formed on the dielectric layer using pattern plating and seed etching processes. Formation of the metallization layers 540 and 542 may also employ surface roughness (SR) processing, surface treatment, and solder-on-pad (SOP) operations.

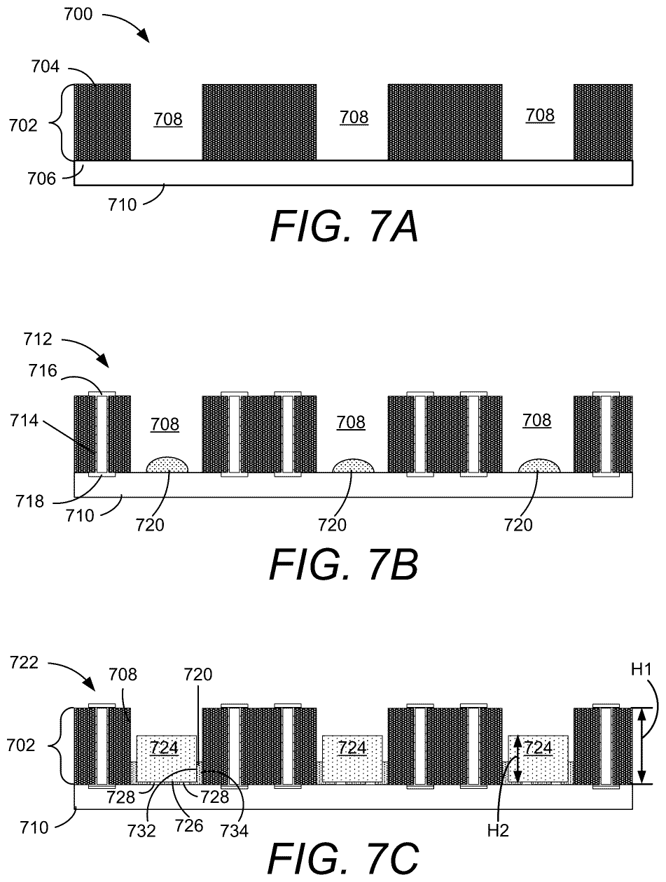

FIGS. 6A and 6B are cross-sectional views of an example substrate 600, according to aspects of the disclosure. As shown in FIG. 6A, the substrate 600 includes an array of electronic components 602 embedded in a core 604. FIG. 6B is an exploded view of region 606 of the substrate 600 shown in FIG. 6A.

As shown in FIG. 6B, the substrate 600 includes an electronic component 602 having a lower planar surface 608 and an upper planar surface 610. The lower planar surface 608 of the electronic component 602 includes one or more electronic component terminals 612 that provide an electrical connection with the electronic component 602.

The core 604 includes a lower planar surface 614 and an upper planar surface 616. A cavity 618 extends through the core 604 between the upper planar surface 616 and the lower planar surface 614. In this example, the thickness H1 of the core 604 is substantially greater than the height H2 of the electronic component 602. In accordance with various aspects of the disclosure, the core 604 may be a thin core having a thickness H1 that is less than or equal to 760 micrometers (μm). Alternatively, the core may be a thick core having a thickness H1 that is greater than 760 μm (e.g., equal to or greater than 820 μm, equal to or greater than 1240 μm, etc.)

In accordance with various aspects of the disclosure, the electronic component 602 is mounted within the cavity 618 in a cured resin layer 620. In the example shown in FIG. 6B, the cured resin layer 620 fills the regions of the cavity 618 between the upper planar surface 610 of the electronic component 602 and a lowermost dielectric layer 622 of an upper metallization structure 624 disposed over the upper planar surface 616 of the core 604. In an aspect, the cured resin layer 620 also at least partially fills the regions of the cavity 618 between the interior sidewalls of the core 604 and the exterior sidewalls of the electronic component 602.

As noted, the thickness H1 of the core 604 (and, therefore, the depth of the cavity 618) is substantially greater than the height H2 of the electronic component 602. As such, there is a substantial portion of the cavity 618 that is not filled with the cured resin layer 620. For very thick core options (e.g., core thicknesses >=820 um), it may be difficult to adequately fill the remaining portions of the cavity 618 with the filler material 628 (e.g., dielectric material), even in the presence of the resin layer 620. In an aspect, a second resin layer 626 may be used to decrease the cavity 618 volume before filling the remaining open portions of the cavity 618 with a filler material 628. Accordingly, a further cured resin layer 626 is formed over the cured resin layer 620. In this example, the further cured resin layer 626 fills the regions between the exterior sidewalls of the electronic component 602 and the interior sidewalls of the core 604 that are not filled by the cured resin layer 620. Additionally, the further cured resin layer 620 fills a portion of the cavity 618 beneath the lower planar surface 608 of the electronic component 602. In an aspect, the cured resin layer 620 and the further cured resin layer 626 may be formed from the same resin material. Alternatively, the cured resin layer 620 and the further cured resin layer 626 may be formed from different resin materials. In an aspect, any remaining portions of the cavity 618 that are not filled by either the cured resin layer 620 or the further cured resin layer 626 may be filled with a filler material 628 (e.g., a dielectric material).

In the example shown in FIG. 6B, the upper metallization structure 624 is configured to provide one or more conductive paths between the one or more electronic component terminals 612 and one or more upper metal terminals 630 of the upper metallization structure 624. Here, the conductive paths are formed by vias (e.g., via 632) extending between one or more dielectric layers (e.g., dielectric layer 634) that connect one or more patterned metal layers (e.g., patterned metal layers 636). In an aspect, the upper metal terminals 630 may be configured for connection with a surface-mounted electronic package (not shown in FIG. 6B). Additionally, or in the alternative, the upper metal terminals 630 may be configured for connecting the substrate 600 with other electronic components (e.g., active components, passive components, integrated circuits, etc.).

Core vias (e.g., via 638) connect one or more of the patterned metal layers (e.g., patterned metal layer 640) of the upper metallization structure 624 with one or more patterned layers (e.g., patterned metal layer 642) of a lower metallization structure 644 to electrically connect the upper metallization structure 624 with the lower metallization structure 644. The lower metallization structure 644 provides one or more conductive paths between the patterned metal layer 642 and one or more metal terminals 646 of the lower metallization structure 644. The metal terminals 646 may be configured for connecting the substrate 600 with other electronic components (e.g., active components, passive components, integrated circuits, etc.), including surface-mounted electronic packages (not shown in FIG. 6B).

The cured resin layer 620 and further cured resin layer 626 keep the electronic component 602 fixed in the cavity 618 and provide substantially void-free solid materials (e.g., having no voids, or having fewer voids and/or voids of smaller dimensions than the voids typically found in conventional dielectric fills used to embed electronic components under similar geometric filling constraints) thereby providing a robust mounting of the electronic component 602 in the cavity 618. As such, the electronic component 602 is secured within the cavity 618 in a manner that limits the chances that the electronic component 602 will delaminate from the core 604.

In an aspect, the cured resin layer 620 may be initially deposited as a liquid resin in the cavity 618. The electronic component 602 may be at least partially embedded in the liquid resin before the liquid resin is cured to form the cured resin layer 620. In this manner, the electronic component 602 may be held in position in the cavity 618 as the remaining portions of the cavity 618 that are not initially filled with the cured resin layer 620 are filled to form the further cured resin layer 626 and the filling material 628. In the example shown in FIG. 6B, the filling material 628 may be a dielectric material. In an aspect, the dielectric material used as the filling material 628 may be the same dielectric material used to form one or more of the dielectric layers (e.g., dielectric layer 650) of the lower metallization structure 644.

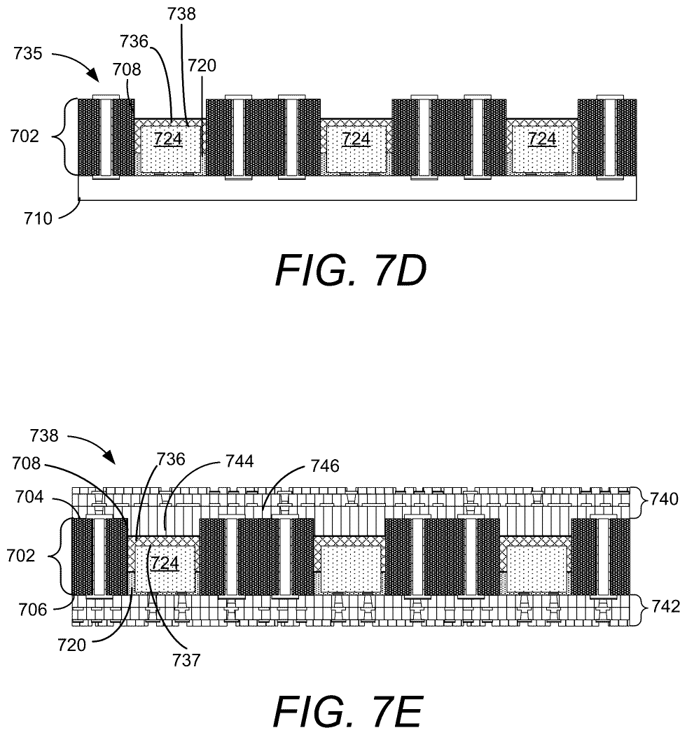

FIGS. 7A through 7E illustrate example operations that may be performed during the fabrication of an example substrate, according to aspects of the disclosure. FIG. 7A shows a first intermediate state 700 of the substrate during the example fabrication process, according to aspects of the disclosure. In this example, the first intermediate state 700 of the substrate includes a core 702 with a first planar surface 704 and a second planar surface 706. In an aspect, the core 702 is subject to a drilling operation to form the cavities 708 that extend between the first planar surface 704 and the second planar surface 706 of the core 702. A layer of polyimide (PI) tape 710 is secured on the second planar surface 706 of the core 702 over the openings of the cavities 708.

FIG. 7B shows a second intermediate state 712 of the substrate during the example fabrication process, according to aspects of the disclosure. In this example, via holes have been drilled through the core 702. The via holes have been subject to metallization and tenting operations to form core vias (e.g., core via 714). Here, the core vias (e.g., core via 714) connect patterned metallization layers (e.g., patterned metallization layers 716, 718) at the first planar surface 704 and the second planar surface 706 of the core 702. An amount of liquid resin 720 is placed on a planar surface of the PI tape 710 at a central location within each cavity 708.

FIG. 7C shows a third intermediate state 722 of the substrate during the example fabrication process, according to aspects of the disclosure. Here, an electronic component 724 is inserted in each cavity 708. In this example, each electronic component 724 has a height H2 that is substantially less than the thickness H1 of the core 702. In accordance with various aspects of the disclosure, the electronic components 724 may be one or more of an active electronic component, a passive electronic component (e.g., a deep trench capacitor (DTC)), a die, etc.

As shown, each electronic component 724 is inserted into the cavity 708 so that a planar surface 726 of the electronic component 724 and its corresponding electronic component terminals 728 are at least partially embedded in the liquid resin 720 of the cavity 708. In this example, the electronic component 724 displaces the liquid resin 720 so that the liquid resin 720 fills the region between the PI tape 710 and the planar surface 726 of the electronic component 724. Additionally, depending on the amount of liquid resin 720 dispensed in the cavity 708, the electronic component 724 may displace the liquid resin 720 to an extent that the liquid resin 720 surrounds the portions of the sidewalls of the cavity 708 (e.g., fills the regions between the outer exterior sidewalls 732 of the electronic component 724 and the inner sidewalls 734 of the cavity 708). Once each electronic component 724 is positioned within its respective cavity 708, the liquid resin 720 is cured (e.g., thermally cured on a hotplate). The liquid resin 720 now forms a cured resin layer (still identified using reference number 720) in each cavity 708, which retains the electronic component 724 in place during subsequent substrate fabrication operations (e.g., filling of the portions of the cavity 708 that are not yet filled with the cured resin layer 720).

FIG. 7D shows a fourth intermediate state 735 of the substrate during the example fabrication process, according to aspects of the disclosure. Here, a further amount of liquid resin is dispensed in each cavity 708. The further amount of liquid resin is cured to form a further cured resin layer 736. In this example, the further cured resin layer 736 fills a portion of the cavity 708 that is not filled with the cured resin layer 720, including a portion of the cavity 708 overlying the upper planar surface 737 of the electronic component 724.

FIG. 7E shows the formation of a completed substrate 738, according to aspects of the disclosure. Here, the layer of PI tape 710 is removed. A first metallization structure 740 is formed over the first planar surface 704 of the core 702 and a second metallization structure 742 is formed over the second planar surface 706 of the core 702. In this example, the portions of the cavity 708 that are not filled with the cured resin layer 720 or the further cured resin layer 736 have been filled with a dielectric material 744. In an aspect, the dielectric material 744 may be the same dielectric material used to form one or more of the dielectric layers (e.g., dielectric layer 746) of the first metallization structure 740.

In accordance with certain aspects of the disclosure, the formation of the metallization structures 740 and 742 may include an initial dielectric lamination operation over each of the planar surfaces 704, 706 of the core 702. The initial dielectric lamination operation may be followed by one or more layer build-up operations. In an aspect, each layer build-up operation may be conducted using a semi-additive process (SAP). In accordance with such SAPs, each dielectric layer is deposited and then laser drilled to form via holes, which are subject to an electroless plating process to deposit metal on the walls of the via holes. If the via structure remains hollow after the electroless plating process, it may be filled with a plugging ink. During the build-up operation, a patterned metallization layer may be formed on the dielectric layer using pattern plating and seed etching processes. Formation of the metallization structures 740 and 742 may also employ surface roughness (SR) processing, surface treatment, and solder-on-pad (SOP) operations.

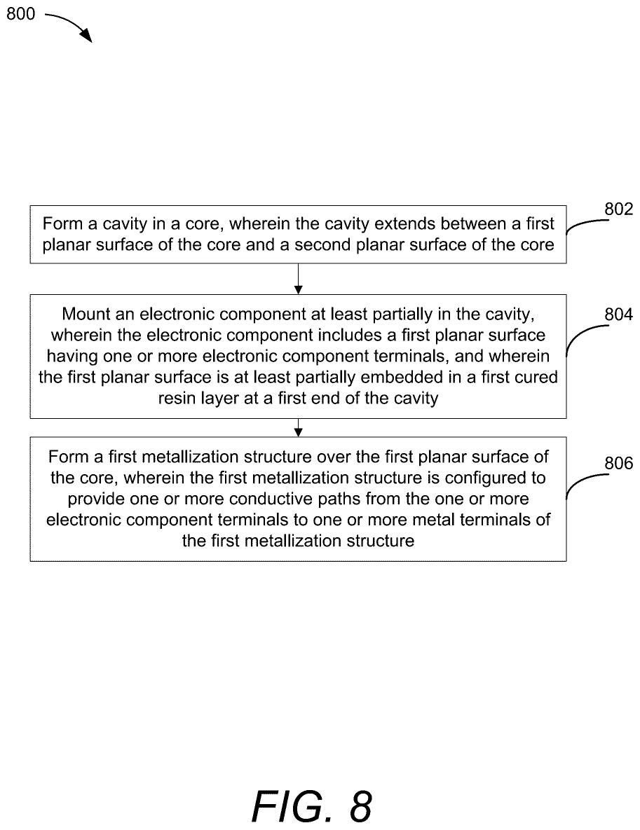

FIG. 8 is a flowchart showing an example method of 800 for fabricating a substrate, according to aspects of the disclosure. At operation 802, a cavity is formed in a core, wherein the cavity extends between a first planar surface of the core and a second planar surface of the core. At operation 804, an electronic component is mounted at least partially in the cavity, wherein the electronic component includes a first planar surface having one or more electronic component terminals, and wherein the first planar surface is at least partially embedded in a first cured resin layer at a first end of the cavity. At operation 806, a first metallization structure is formed over the first planar surface of the core, wherein the first metallization structure is configured to provide one or more conductive paths from the one or more electronic component terminals to one or more metal terminals of the first metallization structure.

In some aspects, the mounting of the electronic component comprises: placing a polyimide (PI) tape over an opening at the first end of the cavity; dispensing a liquid resin in the cavity on the PI tape; inserting the electronic component into the cavity so that the first planar surface of the electronic component is at least partially embedded in the liquid resin; and curing the liquid resin to form the first cured resin layer.

In some aspects, the method includes filling, with a filler material, one or more regions of the cavity that are not filled by the first cured resin layer, wherein the filler material comprises a dielectric filler having a same dielectric material as at least one dielectric layer of the first metallization structure; a further amount of liquid resin that is cured to form a second cured resin layer adjacent the first cured resin layer; a further amount of liquid resin that is cured to form a second cured resin layer adjacent the first cured resin layer; or a combination thereof.

In some aspects, the electronic component comprises a deep trench capacitor.

A technical advantage of the method 800 is that it may be used to form a substrate with an embedded electronic component (e.g., deep trench capacitor) in which the embedded electronic component is robustly mounted in a cavity of the substrate. The robustness of the mount is not as dependent on the size of the electronic component or the thickness of the core as electronic component embedding processes using conventional cavity fills.

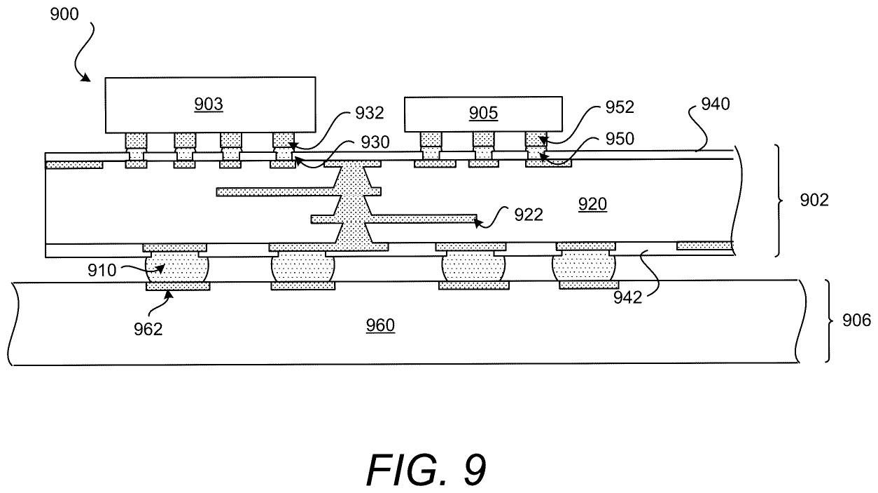

FIG. 9 illustrates a profile view of a package 900 that includes a surface mount substrate 902, an integrated device 903, and an integrated passive device 905 (e.g., a substrate having an embedded electronic component in a core), according to aspects of the disclosure. The package 900 may be coupled to a printed circuit board (PCB) 906 through a plurality of solder interconnects 910. The PCB 906 may include at least one board dielectric layer 960 and a plurality of board interconnects 962.

The surface mount substrate 902 includes at least one dielectric layer 920 (e.g., substrate dielectric layer), a plurality of interconnects 922 (e.g., substrate interconnects), a solder resist layer 940 and a solder resist layer 942. The integrated device 903 may be coupled to the surface mount substrate 902 through a plurality of solder interconnects 930. The integrated device 903 may be coupled to the surface mount substrate 902 through a plurality of pillar interconnects 932 and the plurality of solder interconnects 930. The integrated passive device 905 may be coupled to the surface mount substrate 902 through a plurality of solder interconnects 950. The integrated passive device 905 may be coupled to the surface mount substrate 902 through a plurality of pillar interconnects 952 and the plurality of solder interconnects 950.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 6G, 5G). The package (e.g., 900.) may be configured to support Global System for Mobile (GSM) Communications, Universal Mobile Telecommunications System (UMTS), and/or Long-Term Evolution (LTE). The package (e.g., 900) may be configured to transmit and receive signals having different frequencies and/or communication protocols.

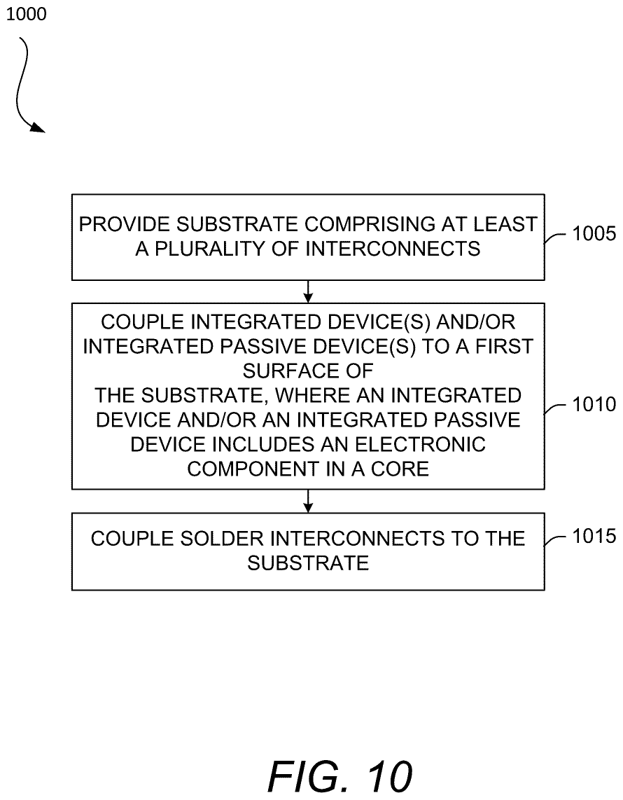

FIG. 10 illustrates an example method 1000 for providing or fabricating a package that includes an integrated device comprising a package substrate (e.g., a substrate having an embedded electronic component in a core), according to aspects of the disclosure. In some implementations, the method 1000 of FIG. 10 may be used to provide or fabricate the package 900 of FIG. 9 described in the disclosure. However, the method 1000 may be used to provide or fabricate any of the packages described in the disclosure.

It should be noted that the method of FIG. 10 may combine one or more processes in order to simplify and/or clarify the method for providing or fabricating a package that includes an integrated device comprising a magnetic layer and/or an integrated passive device comprising a magnetic layer. In some implementations, the order of the processes may be changed or modified.

The method provides (at 1005) a substrate (e.g., 902). The substrate 902 may be provided by a supplier or fabricated. The substrate 902 includes at least one dielectric layer 920, and a plurality of interconnects 922. The substrate 902 may include an embedded trace substrate (ETS). In some implementations, the at least one dielectric layer 920 may include prepreg layers.

The method couples (at 1010) at least one integrated device (e.g., 903) to the first surface of the substrate (e.g., 902). For example, the integrated device 903 may be coupled to the substrate 902 through the plurality of pillar interconnects 932 and the plurality of solder interconnects 930. The plurality of pillar interconnects 932 may be optional. The plurality of solder interconnects 930 are coupled to the plurality of interconnects 922. A solder reflow process may be used to couple the integrated device 903 to the plurality of interconnects through the plurality of solder interconnects 930.

The method also couples (at 1010) at least one integrated passive device (e.g., 905) to the first surface of the substrate (e.g., 902). For example, the integrated passive device 905 may be coupled to the substrate 902 through the plurality of pillar interconnects 952 and the plurality of solder interconnects 950. The plurality of pillar interconnects 952 may be optional. The plurality of solder interconnects 950 are coupled to the plurality of interconnects 922. A solder reflow process may be used to couple the integrated passive device 905 to the plurality of interconnects through the plurality of solder interconnects 950.

The method couples (at 1015) a plurality of solder interconnects (e.g., 910) to the second surface of the substrate (e.g., 902). A solder reflow process may be used to couple the plurality of solder interconnects 910 to the substrate.

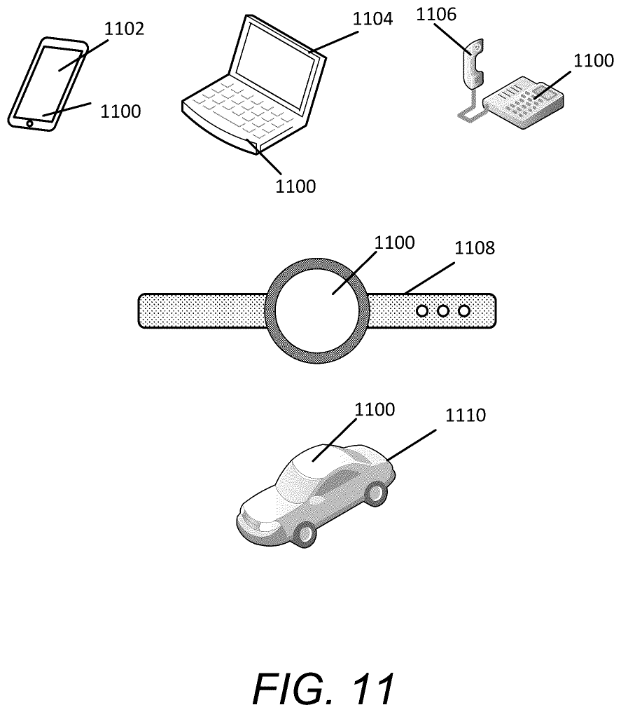

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: a substrate comprising a core having an upper planar surface and a lower planar surface, wherein the core includes a cavity extending between the upper planar surface of the core and the lower planar surface of the core; an electronic component at least partially disposed in the cavity, wherein the electronic component has an upper planar surface having one or more electronic component terminals; a first cured resin layer, wherein the upper planar surface of the electronic component is at least partially embedded in the first cured resin layer at least at an upper portion of the cavity; and an upper metallization structure disposed over the upper planar surface of the core, wherein the upper metallization structure is configured to provide one or more conductive paths from the one or more electronic component terminals to one or more upper metal terminals of the upper metallization structure.

Aspect 2. The electronic device of aspect 1, wherein: the first cured resin layer fills a region between the upper planar surface of the electronic component and a lower dielectric layer of the upper metallization structure.

Aspect 3. The electronic device of any of aspects 1 to 2, wherein: the core includes a plurality of interior sidewalls; the electronic component includes a plurality of exterior sidewalls facing the plurality of interior sidewalls of the core; and the first cured resin layer fills regions between the plurality of exterior sidewalls of the electronic component and the plurality of interior sidewalls of core.

Aspect 4. The electronic device of aspect 3, further comprising: a dielectric filler disposed in at least a portion of the cavity below the first cured resin layer.

Aspect 5. The electronic device of aspect 4, wherein: the electronic component has a height that is greater than or equal to a depth of the core.

Aspect 6. The electronic device of aspect 5, wherein: the core has a thickness equal to or less than 760 micrometers.

Aspect 7. The electronic device of any of aspects 4 to 6, further comprising: a lower metallization structure disposed below the lower planar surface of the core, wherein the lower metallization structure is configured to provide one or more conductive paths from a patterned metallization layer disposed over the lower planar surface of the core to one or more lower metal terminals of the lower metallization structure.

Aspect 8. The electronic device of aspect 7, wherein: the dielectric filler comprises a same dielectric material as at least one dielectric layer of the lower metallization structure.

Aspect 9. The electronic device of any of aspects 1 to 8, further comprising: a second cured resin layer filling at least a portion of the cavity below the first cured resin layer and below the lower planar surface of the electronic component.

Aspect 10. The electronic device of aspect 9, further comprising: a lower metallization structure disposed below the lower planar surface of the core and below the second cured resin layer, wherein the second cured resin layer fills the cavity between the first cured resin layer and an upper surface of the lower metallization structure.

Aspect 11. The electronic device of any of aspects 9 to 10, wherein: the first cured resin layer and the second cured resin layer are formed from a same resin material.

Aspect 12. The electronic device of any of aspects 9 to 11, wherein: the electronic component has a height that is less than a depth of the core.

Aspect 13. The electronic device of aspect 12, wherein: the core has a thickness greater than 760 micrometers.

Aspect 14. The electronic device of any of aspects 1 to 13, further comprising: one or more metal vias extending between the upper planar surface of the core and the lower planar surface of the core.

Aspect 15. The electronic device of any of aspects 1 to 14, further comprising: an electronic circuit package mounted at the one or more upper metal terminals of the upper metallization structure.

Aspect 16. The electronic device of any of aspects 1 to 15, wherein: the electronic component comprises a deep trench capacitor.

Aspect 17. The electronic device of any of aspects 1 to 16, wherein the electronic device comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Aspect 18. A substrate, comprising: a core having an upper planar surface and a lower planar surface, wherein the core includes a cavity extending between the upper planar surface of the core and the lower planar surface of the core; an electronic component at least partially disposed in the cavity, wherein the electronic component has an upper planar surface having one or more electronic component terminals; a first cured resin layer, wherein the upper planar surface of the electronic component is at least partially embedded in the first cured resin layer at least at an upper portion of the cavity; and an upper metallization structure disposed over the upper planar surface of the core, wherein the upper metallization structure is configured to provide one or more conductive paths from the one or more electronic component terminals to one or more upper metal terminals of the upper metallization structure.

Aspect 19. The substrate of aspect 18, wherein: the first cured resin layer fills a region between the upper planar surface of the electronic component and a lower dielectric layer of the upper metallization structure.

Aspect 20. The substrate of any of aspects 18 to 19, wherein: the core includes a plurality of interior sidewalls; the electronic component includes a plurality of exterior sidewalls facing the plurality of interior sidewalls of the cavity; and the first cured resin layer fills regions between the plurality of exterior sidewalls of the electronic component and the plurality of interior sidewalls of the core.

Aspect 21. The substrate of aspect 20, further comprising: a dielectric filler filling at least a portion of the cavity below the first cured resin layer.

Aspect 22. The substrate of aspect 21, wherein: the electronic component has a height that is greater than or equal to a depth of the core.

Aspect 23. The substrate of any of aspects 18 to 22, further comprising: a second cured resin layer filling at least a portion of the cavity below the first cured resin layer and below the lower planar surface of the electronic component.

Aspect 24. The substrate of aspect 23, wherein: the first cured resin layer and the second cured resin layer are formed from a same resin material.

Aspect 25. The substrate of any of aspects 23 to 24, wherein: the electronic component has a height that is less than a depth of the core.

Aspect 26. The substrate of any of aspects 18 to 25, wherein: the electronic component comprises a deep trench capacitor.

Aspect 27. A method for making a substrate, comprising: forming a cavity in a core, wherein the cavity extends between a first planar surface of the core and a second planar surface of the core; mounting an electronic component at least partially in the cavity, wherein the electronic component includes a first planar surface having one or more electronic component terminals, and wherein the first planar surface of the electronic component is at least partially embedded in a first cured resin layer at a first end of the cavity; and forming a first metallization structure over the first planar surface of the core, wherein the first metallization structure is configured to provide one or more conductive paths from the one or more electronic component terminals to one or more metal terminals of the first metallization structure.

Aspect 28. The method of aspect 27, wherein the mounting of the electronic component comprises: placing a polyimide (PI) tape over an opening at the first end of the cavity; dispensing a liquid resin in the cavity on the PI tape; inserting the electronic component into the cavity so that the first planar surface of the electronic component is at least partially embedded in the liquid resin; and curing the liquid resin to form the first cured resin layer.

Aspect 29. The method of aspect 28, further comprising: filling, with a filler material, one or more regions of the cavity that are not filled by the first cured resin layer, wherein the filler material comprises a dielectric filler having a same dielectric material as at least one dielectric layer of the first metallization structure; a further amount of liquid resin that is cured to form a second cured resin layer adjacent the first cured resin layer; or a combination thereof.

Aspect 30. The method of any of aspects 28 to 29, wherein: the electronic component comprises a deep trench capacitor.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component).

Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a substrate comprising:
a core having an upper planar surface and a lower planar surface, wherein the core includes a cavity extending between the upper planar surface of the core and the lower planar surface of the core;
an electronic component at least partially disposed in the cavity, wherein the electronic component has an upper planar surface having one or more electronic component terminals;
a first cured resin layer, wherein the upper planar surface of the electronic component is at least partially embedded in the first cured resin layer at least at an upper portion of the cavity; and
an upper metallization structure disposed over the upper planar surface of the core, wherein the upper metallization structure is configured to provide one or more conductive paths from the one or more electronic component terminals to one or more upper metal terminals of the upper metallization structure.

2. The electronic device of claim 1, wherein:
the first cured resin layer fills a region between the upper planar surface of the electronic component and a lower dielectric layer of the upper metallization structure.

3. The electronic device of claim 1, wherein:
the core includes a plurality of interior sidewalls;
the electronic component includes a plurality of exterior sidewalls facing the plurality of interior sidewalls of the core; and
the first cured resin layer fills regions between the plurality of exterior sidewalls of the electronic component and the plurality of interior sidewalls of core.

4. The electronic device of claim 3, further comprising:
a dielectric filler disposed in at least a portion of the cavity below the first cured resin layer.

5. The electronic device of claim 4, wherein:
the electronic component has a height that is greater than or equal to a depth of the core.

6. The electronic device of claim 5, wherein:
the core has a thickness equal to or less than 760 micrometers.

7. The electronic device of claim 4, further comprising:
a lower metallization structure disposed below the lower planar surface of the core, wherein the lower metallization structure is configured to provide one or more conductive paths from a patterned metallization layer disposed over the lower planar surface of the core to one or more lower metal terminals of the lower metallization structure.

8. The electronic device of claim 7, wherein:
the dielectric filler comprises a same dielectric material as at least one dielectric layer of the lower metallization structure.

9. The electronic device of claim 1, further comprising:
a second cured resin layer filling at least a portion of the cavity below the first cured resin layer and below the lower planar surface of the electronic component.

10. The electronic device of claim 9, further comprising:
a lower metallization structure disposed below the lower planar surface of the core and below the second cured resin layer, wherein the second cured resin layer fills the cavity between the first cured resin layer and an upper surface of the lower metallization structure.

11. The electronic device of claim 9, wherein:
the first cured resin layer and the second cured resin layer are formed from a same resin material.

12. The electronic device of claim 9, wherein:
the electronic component has a height that is less than a depth of the core.

13. The electronic device of claim 12, wherein:
the core has a thickness greater than 760 micrometers.

14. The electronic device of claim 1, further comprising:
one or more metal vias extending between the upper planar surface of the core and the lower planar surface of the core.

15. The electronic device of claim 1, further comprising:
an electronic circuit package mounted at the one or more upper metal terminals of the upper metallization structure.

16. The electronic device of claim 1, wherein:
the electronic component comprises a deep trench capacitor.

17. The electronic device of claim 1, wherein the electronic device comprises at least one of:
a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

18. A substrate, comprising:
a core having an upper planar surface and a lower planar surface, wherein the core includes a cavity extending between the upper planar surface of the core and the lower planar surface of the core;
an electronic component at least partially disposed in the cavity, wherein the electronic component has an upper planar surface having one or more electronic component terminals;
a first cured resin layer, wherein the upper planar surface of the electronic component is at least partially embedded in the first cured resin layer at least at an upper portion of the cavity; and
an upper metallization structure disposed over the upper planar surface of the core, wherein the upper metallization structure is configured to provide one or more conductive paths from the one or more electronic component terminals to one or more upper metal terminals of the upper metallization structure.

19. The substrate of claim 18, wherein:
the first cured resin layer fills a region between the upper planar surface of the electronic component and a lower dielectric layer of the upper metallization structure.

20. The substrate of claim 18, wherein:
the core includes a plurality of interior sidewalls;
the electronic component includes a plurality of exterior sidewalls facing the plurality of interior sidewalls of the cavity; and
the first cured resin layer fills regions between the plurality of exterior sidewalls of the electronic component and the plurality of interior sidewalls of the core.

21. The substrate of claim 20, further comprising:
a dielectric filler filling at least a portion of the cavity below the first cured resin layer.

22. The substrate of claim 21, wherein:
the electronic component has a height that is greater than or equal to a depth of the core.

23. The substrate of claim 18, further comprising:
a second cured resin layer filling at least a portion of the cavity below the first cured resin layer and below the lower planar surface of the electronic component.

24. The substrate of claim 23, wherein:
the first cured resin layer and the second cured resin layer are formed from a same resin material.

25. The substrate of claim 23, wherein:
the electronic component has a height that is less than a depth of the core.

26. The substrate of claim 18, wherein:
the electronic component comprises a deep trench capacitor.

27. A method for making a substrate, comprising:
forming a cavity in a core, wherein the cavity extends between a first planar surface of the core and a second planar surface of the core;
mounting an electronic component at least partially in the cavity, wherein the electronic component includes a first planar surface having one or more electronic component terminals, and wherein the first planar surface of the electronic component is at least partially embedded in a first cured resin layer at a first end of the cavity; and
forming a first metallization structure over the first planar surface of the core, wherein the first metallization structure is configured to provide one or more conductive paths from the one or more electronic component terminals to one or more metal terminals of the first metallization structure.

28. The method of claim 27, wherein the mounting of the electronic component comprises:
placing a polyimide (PI) tape over an opening at the first end of the cavity;
dispensing a liquid resin in the cavity on the PI tape;
inserting the electronic component into the cavity so that the first planar surface of the electronic component is at least partially embedded in the liquid resin; and
curing the liquid resin to form the first cured resin layer.

29. The method of claim 28, further comprising:
filling, with a filler material, one or more regions of the cavity that are not filled by the first cured resin layer, wherein the filler material comprises
a dielectric filler having a same dielectric material as at least one dielectric layer of the first metallization structure;
a further amount of liquid resin that is cured to form a second cured resin layer adjacent the first cured resin layer; or
a combination thereof.

30. The method of claim 28, wherein:
the electronic component comprises a deep trench capacitor.
